(19) United States
(12) Patent Application Publication
(10) Pub. No.: US 2025/0336743 A1
(43) Pub. Date: Oct. 30, 2025

(54) SEMICONDUCTOR PACKAGE

(71) Applicant: SAMSUNG ELECTRONICS CO., LTD, SUWON-SI (KR)

(72) Inventors: Myeonghan Bae, Suwon-si (KR); Jongyoun Kim, Suwon-si (KR); Jingu Kim, Suwon-si (KR)

(21) Appl. No.: 19/095,573

(22) Filed: Mar. 31, 2025

(30) Foreign Application Priority Data
Apr. 30, 2024 (KR) 10-2024-0057688

(51) Int. Cl. H01L 23/31; H01L 23/00; H01L 23/538; H01L 23/544; H01L 25/07

(52) U.S. Cl. CPC H01L 23/3135; H01L 23/5385; H01L 23/544; H01L 24/48; H01L 25/074; H01L 24/45; H01L 2224/45124; H01L 2224/45144; H01L 2224/45147; H01L 2224/48227; H01L 2225/0651; H01L 2225/06562

(57) ABSTRACT

A semiconductor package includes a redistribution wiring layer, an encapsulation structure disposed on the redistribution wiring layer, a plurality of conductive bumps disposed on the encapsulation structure, a second sealing member on the redistribution wiring layer covering the encapsulation structure, and partially exposing the plurality of conductive bumps, and an insulating layer covering an upper surface of the second sealing member and the plurality of conductive bumps. The encapsulation structure includes a first sealing member, a substrate disposed on an upper surface of the first sealing member, a plurality of semiconductor chips sequentially disposed within the first sealing member such that a front surface on which chip pads of each of the plurality of semiconductor chips are formed faces the redistribution wiring layer, and conductive wires extending from a lower surface of the first sealing member to the chip pads of the plurality of semiconductor chips, respectively.

### CROSS-REFERENCE TO RELATED APPLICATION(S)

This application claims priority under 35 U.S.C. § 119 to Korean Patent Application No. 10-2024-0057688, filed on Apr. 30, 2024 in the Korean Intellectual Property Office, the disclosure of which is incorporated by reference in its entirety herein.

### 1. TECHNICAL FIELD

Example embodiments relate to a semiconductor package and a method of manufacturing the semiconductor package. More particularly, example embodiments relate to a multi-chip package including a plurality of stacked chips and a method of manufacturing the same.

### 2. DISCUSSION OF RELATED ART

In manufacturing a fan-out package, molding structures each including a plurality of semiconductor chips may be attached to a carrier substrate by a chip-on-wafer (COW) bonding method using an adhesive film such as a die attach film (DAF). A redistribution wiring layer may then be formed on a surface of the molding structure. However, the manufacturing process may include the formation of a metal layer for attachment to the adhesive film, a metal layer for an alignment key pattern for aligning the molding structure and a marking pattern in an insulating layer on the carrier substrate. Thus, there is a problem that a package manufacturing process becomes complicated and the adhesive reliability of the adhesive film decreases.

### SUMMARY

Example embodiments provide a semiconductor package capable of simplifying a package manufacturing process and having increased reliability.

Example embodiments provide a method of manufacturing the semiconductor package.

According to an embodiment of the present disclosure, a semiconductor package includes a redistribution wiring layer. An encapsulation structure is disposed on the redistribution wiring layer. A plurality of conductive bumps is disposed on the encapsulation structure. A second sealing member is disposed on the redistribution wiring layer, covers the encapsulation structure, and partially exposes the plurality of conductive bumps. An insulating layer covers an upper surface of the second sealing member and the plurality of conductive bumps. The encapsulation structure includes a first sealing member. A substrate is disposed on an upper surface of the first sealing member. A plurality of semiconductor chips is sequentially disposed within the first sealing member. Chip pads of each of the plurality of semiconductor chips are disposed on a front surface of the plurality of semiconductor chips, respectively. The front surface faces the redistribution wiring layer. Conductive wires extend from a lower surface of the first sealing member to the chip pads of the plurality of semiconductor chips, respectively.

According to an embodiment of the present disclosure, a semiconductor package includes a redistribution wiring layer. A first sealing member is disposed on the redistribution wiring layer. A plurality of semiconductor chips is sequentially disposed in the first sealing member. Chip pads of each of the plurality of semiconductor chips are disposed on a front surface of the plurality of semiconductor chips, respectively. The front surface faces the redistribution wiring layer. Conductive wires extend from a lower surface of the first sealing member to the chip pads of the plurality of semiconductor chips, respectively. A substrate is disposed on an upper surface of the first sealing member. A plurality of conductive bumps is disposed on the substrate. A second sealing member is on the redistribution wiring layer and covers the first sealing member and the substrate. The second sealing member partially exposes the plurality of conductive bumps. An insulating layer covers an upper surface of the second sealing member. A plurality of bonding pads is disposed in the insulating layer and is respectively in direct contact with the plurality of conductive bumps. A marking pattern is arranged in the insulating layer.

According to an embodiment of the present disclosure, a semiconductor package includes a redistribution wiring layer. An encapsulation structure is disposed on the redistribution wiring layer. The encapsulation structure includes a first sealing member, a plurality of semiconductor chips sequentially stacked in the first sealing member and offset aligned in a first horizontal direction with respect to each other. Chip pads of each of the plurality of semiconductor chips are disposed on a front surface of the plurality of semiconductor chips, respectively. The front surface faces the redistribution wiring layer. Conductive wires extend from a lower surface of the first sealing member to the chip pads of the plurality of semiconductor chips. A substrate is disposed on an upper surface of the first sealing member. A plurality of conductive bumps is disposed on the substrate. A second sealing member is disposed on the redistribution wiring layer and covers the encapsulation structure. The second sealing member partially exposes the plurality of conductive bumps. An insulating layer covers an upper surface of the second sealing member. A plurality of bonding pads is disposed in the insulating layer. The plurality of bonding pads is respectively in direct contact with the plurality of conductive bumps. A marking pattern is arranged in the insulating layer.

According to an embodiment of the present disclosure, a method of manufacturing a semiconductor package includes forming an encapsulation structure including a substrate, a plurality of semiconductor chips sequentially stacked on the substrate, conductive wires extending vertically on chip pads of the plurality of semiconductor chips, the chip pads are formed on a front surface of the plurality of semiconductor chips, and a first sealing member covering the plurality of semiconductor chips and the conductive wires on the substrate. An insulating layer is formed having a plurality of bonding pads. The encapsulation structure is bonded onto the insulating layer via a plurality of conductive bumps that is respectively bonded onto the plurality of bonding pads. A second sealing member is formed covering the encapsulation structure on the insulating layer. A redistribution wiring layer is formed on the second sealing member and the encapsulation structure. The redistribution wiring layer has redistribution wirings that are electrically connected to the conductive wires.

According to an embodiment, a semiconductor package may include a redistribution wiring layer, an encapsulation structure stacked on the redistribution wiring layer, a plurality of conductive bumps disposed on the encapsulation structure, a second sealing member covering the encapsulation structure on the redistribution wiring layer and partially exposing the plurality of conductive bumps, and an insulating layer covering an upper surface of the second sealing member. The encapsulation structure may include a first sealing member, a substrate disposed on the first sealing member, a plurality of semiconductor chips arranged within the first sealing member, and a plurality of conductive wires extending on chip pads of the plurality of semiconductor chips within the first sealing member. The chip pads of the plurality of semiconductor chips may be electrically connected to redistribution wirings of the redistribution wiring layer by the conductive wires.

In an embodiment, the insulating layer may be provided with a plurality of bonding pads and a marking pattern. The conductive bumps may be interposed between the encapsulation structure and the insulating layer. The conductive bumps may be interposed between substrate pads of the substrate and bonding pads of the insulating layer.

In an embodiment, the encapsulation structure may be bonded on the insulating layer in such a way that the conductive bumps are respectively bonded to the bonding pads. According to a comparative example, since the individually separated encapsulation structures are attached to the insulating layer by an adhesive film such as DAF, it may be necessary to separately form an alignment key pattern on the insulating layer. In addition, it may be necessary to form an additional metal film for the marking pattern. In example embodiments, since the encapsulation structure is attached using the conductive bumps, the encapsulation structure may be easily aligned, the package manufacturing process may be simplified, and the strength of the package may be increased.

### BRIEF DESCRIPTION OF THE DRAWINGS

Example embodiments will be more clearly understood from the following detailed description taken in conjunction with the accompanying drawings. FIGS. 1 to 21 represent non-limiting, example embodiments as described herein.

FIG. 1 is a cross-sectional view illustrating a semiconductor package in accordance with an embodiment of the present disclosure.

FIG. 2 is a plan view illustrating the semiconductor package in FIG. 1 according to an embodiment of the present disclosure.

FIGS. 3 to 21 are views illustrating a method of manufacturing a semiconductor package in accordance with embodiments of the present disclosure.

### DETAILED DESCRIPTION OF EMBODIMENTS

Hereinafter, non-limiting embodiments will be explained in detail with reference to the accompanying drawings.

The present inventive concept concerns a semiconductor package that includes an encapsulation structure that is bonded onto an insulating layer by conductive bumps. For example, substrate pads of a substrate of the encapsulation structure and bonding pads of the insulating layer may directly contact opposite surfaces of the conductive bumps. Thus, the encapsulation structure may be easily aligned in the manufacturing process and the need for an alignment key pattern and an additional metal layer for a marking pattern is obviated. Accordingly, the semiconductor package may have increased strength and a relatively simple manufacturing process.

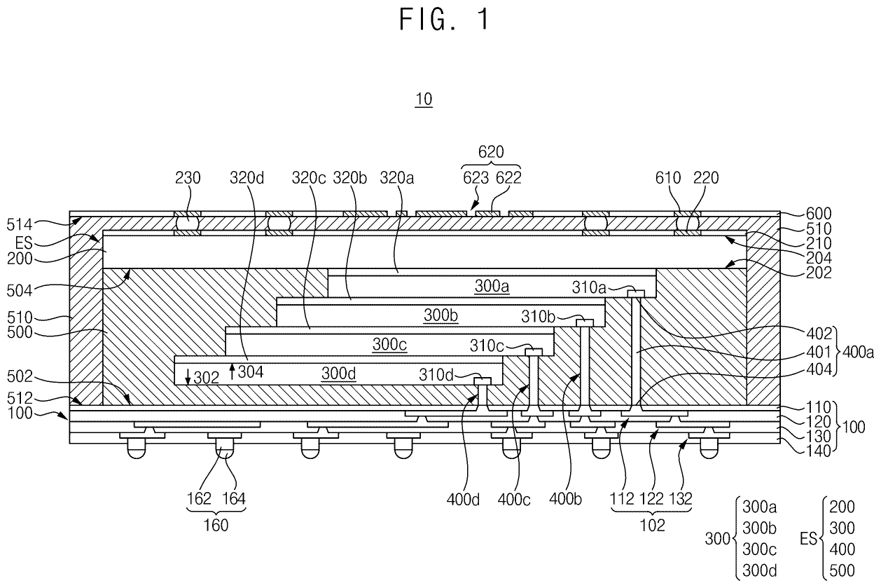

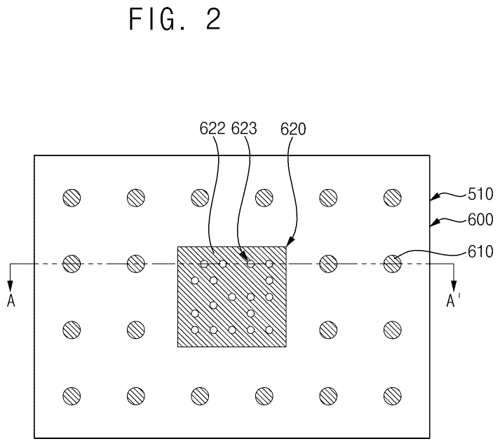

FIG. 1 is a cross-sectional view illustrating a semiconductor package in accordance with example embodiments. FIG. 2 is a plan view illustrating the semiconductor package in FIG. 1.

Referring to FIGS. 1 and 2, in an embodiment a semiconductor package 10 may include a redistribution wiring layer 100, a encapsulation structure ES disposed on the redistribution wiring layer 100, a plurality of conductive bumps 230 disposed on the encapsulation structure ES, a second sealing member 510 covering the encapsulation structure ES on the redistribution wiring layer and partially exposing the plurality of conductive bumps 230, and an insulating layer 600 covering an upper surface 514 of the second sealing member 510. In an embodiment, the encapsulation structure ES may include a first sealing member 500, a plurality of semiconductor chips 300 disposed in the first sealing member 500, and conductive wires 400 as a plurality of vertical conductive structures in the first sealing member 500 and extending from chip pads 310 of the plurality of semiconductor chips 300. Additionally, the semiconductor package 10 may further include external connection members 160 disposed on an outer side surface of the redistribution wiring layer 100. For example, in an embodiment the outer side surface of the redistribution wiring layer 100 may be a bottom surface of the redistribution wiring layer 100.

In an embodiment, the semiconductor package 10 may be a fan-out package in which the redistribution wiring layer 100 is formed to extend to the second sealing member 510 that covers an outer surface of the encapsulation structure ES including the semiconductor chips 300. The redistribution wiring layer 100 may be formed by a wafer-level redistribution wiring process. In addition, in an embodiment the semiconductor package 10 may be provided as an upper package that is stacked on a lower package.

Additionally, in an embodiment the semiconductor package 10 may be provided as a System In Package (SIP). For example, one or more semiconductor chips may be disposed on the redistribution wiring layer 100. In an embodiment, the semiconductor chips may include a logic chip including a logic circuit and/or a memory chip. The logic chip may be a controller that controls memory chips. The memory chip includes various types of memory circuits, such as DRAM, SRAM, flash, PRAM, ReRAM, FeRAM, or MRAM.

In an embodiment, the redistribution wiring layer 100 may have redistribution wirings 102. The encapsulation structure ES including the plurality of semiconductor chips 300 electrically connected to the redistribution wirings 102 may be stacked on the redistribution wiring layer 100. In an embodiment, the redistribution wiring layer 100 may be a front redistribution wiring layer (FRDL) of the fan-out package.

In an embodiment, the redistribution wiring layer 100 may include a plurality of insulating layers, such as first, second, third and fourth lower insulating layers 110, 120, 130 and 140 and the redistribution wirings 102 may be provided in the first, second, third and fourth lower insulating layers. In an embodiment, the redistribution wirings 102 may include first, second and third redistribution wirings 112, 122 and 132.

The first, second, third and fourth lower insulating layers may include a polymer, a dielectric layer, etc. For example, the first, second, third and fourth lower insulating layers may include a photosensitive insulating layer such as PID (photo imagable dielectric). In an embodiment, the first, second, third and fourth lower insulating layers may be formed by a vapor deposition process, a spin coating process, etc. In an embodiment, the redistribution wirings may include aluminum (Al), copper (Cu), tin (Sn), nickel (Ni), gold (Au), platinum (Pt), or an alloy thereof. The redistribution wirings may be formed by a plating process, an electroless plating process, a vapor deposition process, etc.

In particular, the first lower insulating layer 110 may be formed on (e.g., disposed directly thereon) the lower surface 502 of the first sealing member 500 and the lower surface 512 of the second sealing member 510, and the first redistribution wirings 112 may be formed on (e.g. disposed directly thereon) the first lower insulating layer 110. The first redistribution wirings 112 may be electrically connected to the conductive wires 400 through first openings formed in the first lower insulating layer 110.

The second lower insulating layer 120 may be formed on (e.g., disposed directly thereon) the first lower insulating layer 110, and the second redistribution wirings 122 may be formed on (e.g., formed directly thereon) the second lower insulating layer 120. The second redistribution wirings 122 may be electrically connected to the first redistribution wirings 112 through second openings formed in the second lower insulating layer 120.

The third lower insulating layer 130 may be formed on (e.g., formed directly thereon) the second lower insulating layer 120, and the third redistribution wirings 132 may be formed on the third lower insulating layer 130. The third redistribution wirings 132 may be electrically connected to the second redistribution wirings 122 through third openings formed in the third lower insulating layer 130.

The fourth lower insulating layer 140 may be formed on the third lower insulating layer 130 to expose at least portions of the third redistribution wirings 132. The fourth lower insulating layer 140 may serve as a passivation layer.

It will be understood that the number, size, arrangement, etc. of the insulating layers and the redistribution wirings of the redistribution wiring layer are provided as an example, and embodiments of the present inventive concept are not necessarily limited thereto.

In an embodiment, when viewed in a plan view, the redistribution wiring layer 100 may include a first region overlapping the encapsulation structure ES disposed on an upper surface of the redistribution wiring layer 100 and a second region surrounding the first region. The second region may be a fan-out region outside the region where the semiconductor chip is disposed.

In an embodiment, the encapsulation structure ES may include the first sealing member 500, a substrate 200 provided on (e.g., disposed directly thereon) the upper surface 504 of the first sealing member 500, the plurality of semiconductor chips 300 sequentially stacked within the first sealing member 500 from a first surface 202 of the substrate 200, and the conductive wires 400 extending within the first sealing member 500 from the lower surface 502 of the first sealing member 500 to the chip pads 310 of the plurality of semiconductor chips 300.

The plurality of semiconductor chips 300 may be sequentially stacked within the first sealing member 500. In an embodiment, the plurality of semiconductor chips 300 may be arranged such that a front surface 302 of the plurality of semiconductor chips 300 on which the chip pads 310 are formed faces the redistribution wiring layer 100. In an embodiment, each of the semiconductor chips 300 may have a rectangular shape with four sides when viewed in a plan view. The chip pads 310 may be disposed in a peripheral region along one side of each of the semiconductor chips 300.

In an embodiment as shown in FIG. 1, the plurality of semiconductor chips 300 may include first, second, third, and fourth semiconductor chips 300a, 300b, 300c, and 300d stacked in a cascade structure from the first surface 202 of the substrate 200. However, embodiments of the present disclosure are not necessarily limited thereto and the number of the plurality of semiconductor chips 300 may vary. The first, second, third, and fourth semiconductor chips 300a, 300b, 300c, and 300d may be sequentially attached to the first surface 202 of the substrate 200 using adhesive films 320. In an embodiment, the adhesive films may include die attach film (DAF). For example, a thickness of the semiconductor chip may be within a range of about 40 μm to about 110 μm. The thickness of the adhesive film may be within a range of about 10 μm to about 60 μm.

The second semiconductor chip 300b may be offset aligned in a first horizontal direction with respect to the first semiconductor chip 300a. The second semiconductor chip 300b may be offset aligned in the first horizontal direction such that the chip pads 310a of the first semiconductor chip 300a are exposed from the second semiconductor chip 300b. The third semiconductor chip 300c may be offset aligned in the first horizontal direction with respect to the second semiconductor chip 300b. The third semiconductor chip 300c may be offset aligned in the first horizontal direction such that the chip pads 310b of the second semiconductor chip 300b are exposed from the third semiconductor chip 300c. The fourth semiconductor chip 300d may be offset aligned in the first horizontal direction with respect to the third semiconductor chip 300c. The fourth semiconductor chip 300d may be offset aligned in the first horizontal direction such that the chip pads 310c of the third semiconductor chip 300c are exposed from the fourth semiconductor chip 300d.

Each of the first, second, and third semiconductor chips 300a, 300b, and 300c may have an overhang portion protruding from one side (e.g., a first side) of each of the underlying second, third, and fourth semiconductor chips 300b, 300c, and 300d. For example, each of the first, second and third semiconductor chips 300a, 300b and 300c may have an overhang portion protruding from a first side of the underlying second, third, and fourth semiconductor chips 300b, 300c, and 300d which is a right lateral side in a direction opposite to the first horizontal direction. When viewed from bottom view, the chip pads 310a of the first semiconductor chip 300a may be arranged on a lower surface (e.g., the front surface 302) of the overhang portion protruding from one side (e.g., a first side) of the second, third, and fourth semiconductor chips 300b, 300c, and 300d to be spaced apart from each other along a second horizontal direction perpendicular to the first horizontal direction. When viewed from bottom view, the chip pads 310b of the second semiconductor chip 300b may be arranged on a lower surface (e.g., the front surface 302) of the overhang portion protruding from one side of the third and fourth semiconductor chips 300c and 300d to be spaced apart from each other along the second horizontal direction. When viewed from bottom view, the chip pads 310c of the third semiconductor chip 300c may be arranged on a lower surface (e.g., the front surface 302) of the overhang portion protruding from one side of the fourth semiconductor chip 300d to be spaced apart from each other along the second horizontal direction.

The plurality of semiconductor chips 300 may include a memory chip including a memory circuits. For example, in an embodiment the semiconductor chip may include volatile memory devices such as SRAM devices or DRAM devices, and non-volatile memory devices such as flash memory devices, PRAM devices, MRAM devices or RRAM devices.

It will be understood that the number, size, arrangement, etc. of the semiconductor chips are provided as an example, and embodiments of the present inventive concept are not necessarily limited thereto. Also, although only a few chip pads are illustrated in the figures, it will be understood that the structure, shape, and arrangement of the chip pads are provided as an example, and embodiments of the present inventive concept are not necessarily limited thereto.

In an embodiment, the conductive wires 400 may extend vertically on the chip pads 310 of the first, second, third, and fourth semiconductor chips 300 within the first sealing member 500, respectively. When viewed from a bottom view, the conductive wires 500 may be positioned in an area where the plurality of semiconductor chips 300 are disposed.

For example, in an embodiment the first conductive wire 400a may be a conductive wire that extends from the chip pad 310a of the first semiconductor chip 300a to the lower surface 502 of the first sealing member 500. The second conductive wire 400b may be a conductive wire that extends from the chip pad 310b of the second semiconductor chip 300b to the lower surface 502 of the first sealing member 500. The third conductive wire 400c may be a conductive wire that extends from the chip pad 310c of the third semiconductor chip 300c to the lower surface 502 of the first sealing member 500. The fourth conductive wire 400d may be a conductive wire that extends from the chip pad 310d of the fourth semiconductor chip 300d to the lower surface 502 of the first sealing member 500. The first, second, third and fourth conductive wires may be formed by a bonding wire process. For example, in an embodiment the conductive wire may include copper (Cu), gold (Au), aluminum (Al), etc.

For example, in an embodiment the fourth conductive wire 400d may include a wire body 401 extending in a vertical direction, a first bonding end portion 402 provided at a first end portion of the wire body 401 and bonded to the first chip pad 310a, and a second bonding end portion 404 provided at a second end portion opposite to the first end portion of the wire body 401 (e.g., in a vertical direction) and having a ball shape. The wire body 401 may have a first diameter, and the second bonding end portion 404 may have a second diameter that is greater than the first diameter. For example, in an embodiment the first diameter and the second diameter may be within a range of about 15 μm to about 50 μm.

The end portions, such as the second bonding end portions 404 of the conductive wires 400 may be exposed from the lower surface 502 of the first sealing member 500. For example, recesses may be provided in the lower surface 502 of the first sealing member 500 and may respectively expose the end portions of the conductive wires 400.

In an embodiment, the substrate 200 may be a multilayer circuit board having the first surface 202 and a second surface 204 opposite to the first surface 202 (e.g., in the vertical direction). The substrate 200 may be a printed circuit board (PCB) including a plurality of stacked insulating layers and wirings respectively provided in the insulating layers. In an embodiment, the substrate 200 may include a glass substrate, a silicon substrate, a ceramic substrate, etc.

In an embodiment, an outer side surface of the substrate 200 may be positioned on the same plane as an outer side surface of the first sealing member 500. For example, as shown in an embodiment of FIG. 1, the left outer side surface (e.g., in the first horizontal direction) of the substrate 200 may be positioned on the same plane as the left outer side surface (e.g., in the first horizontal direction) of the first sealing member 500. A plurality of substrate pads 220 may be provided on (e.g., disposed directly thereon) the second surface 204 of the substrate 200 and a passivation layer 210 having openings that expose the plurality of substrate pads 220 may be provided on (e.g., disposed directly thereon) the second surface 204 of the substrate 200. The plurality of substrate pads 220 may be dummy pads to which no electrical signal is transmitted. For example, in an embodiment the passivation layer may include a photosensitive polymer such as photo solder resist (PSR) or a photosensitive resin such as photo epoxy.

In an embodiment, the conductive bumps 230 may be disposed on the plurality of substrate pads 220, respectively. The conductive bumps 230 may include solder bumps, micro balls, etc. In an embodiment, a diameter of each of the conductive bumps 230 may be within a range of about 20 μm to about 50 μm.

In an embodiment, the second sealing member 510 may be provided on the redistribution wiring layer 100 (e.g., disposed directly thereon) and may cover the encapsulation structure ES. The second sealing member 510 may cover the passivation layer 210 of the encapsulation structure ES. The second sealing member 510 may partially expose the plurality of conductive bumps 230 on the substrate 200. For example, the second sealing member 510 may cover side surfaces of the conductive bumps 230 and expose upper and lower surfaces of the conductive bumps 230. The second sealing member 510 may fill spaces between the conductive bumps 230 and the upper surface of the encapsulation structure ES and the insulating layer 600.

An insulating layer 600 may cover the upper surface 514 of the second sealing member 510. A plurality of bonding pads 610 and a marking pattern 620 may be provided in (e.g., arranged in) the insulating layer 600. The conductive bumps 230 may be interposed between (e.g., directly therebetween) the encapsulation structure ES and the insulating layer 600 (e.g., in a vertical direction). The conductive bumps 230 may be interposed between (e.g., directly therebetween) the substrate pads 220 of the substrate 200 and the bonding pads 610 of the insulating layer 600 (e.g., in the vertical direction). Each of the plurality of bonding pads may be in direct contact with the conductive bumps 230, respectively.

For example, the insulating layer 600 may include a polymer, a dielectric layer, etc. In an embodiment, the insulating layer 600 may include a photosensitive insulating material (PID). The insulating layer 600 may include a photosensitive polymer such as photo solder resist (PSR) or a photosensitive resin such as photo epoxy. In an embodiment, the insulating layer may be formed by a spin coating process, a vapor deposition process, or the like. In an embodiment, the bonding pad 610 and the marking pattern 620 may include a same material as each other. In an embodiment, the bonding pad and the marking pattern may include copper (Cu), aluminum (Al), tin (Sn), nickel (Ni), gold (Au), platinum (Pt), or an alloy thereof. However, embodiments of the present inventive concept are not necessarily limited thereto.

As illustrated in FIG. 2, the marking pattern 620 may be positioned in a central region of the insulating layer 600, and the bonding pads 610 may be positioned in a peripheral region surrounding the central region. The bonding pads 610 may be spaced apart from each other in the peripheral region so as to surround the marking pattern 620 (e.g., in a plan view). In an embodiment, the marking pattern 620 may include a marking dummy pattern 623 in the central region and an engraved pattern 622 that is defined by openings that are formed by irradiating a laser on the marking dummy pattern 623. The opening may include a through hole penetrating the marking dummy pattern 623 or a groove having a predetermined depth. In an embodiment, the engraved pattern 622 may display a manufacturer, a manufacturing date, a serial number, etc.

In an embodiment, the first and second sealing members 500 and 510 may include a thermosetting resin, for example, epoxy mold compound (EMC). At least one outer side surface of the redistribution wiring layer 100 may be located on the same plane as at least one outer side surface of the second sealing member 510. In addition, at least one outer side surface of the second sealing member 510 may be located on the same plane as at least one outer side surface of the insulating layer 600. For example, in an embodiment as shown in FIG. 1 both outer side surfaces of each of the second sealing member 510, the redistribution wiring layer 100 and the insulating layer 600 are disposed on the same plane as each other.

In an embodiment, external connection members 160 may be disposed on the lower surface of the redistribution wiring layer 100. For example, in an embodiment each of the external connection members 160 may include a pillar bump 162 formed on (e.g., disposed directly thereon) a lower bonding pad on the third redistribution wiring 132 exposed by the fourth lower insulating layer 140 and a solder bump 164 on (e.g., disposed directly thereon) the pillar bump 162. For example, in an embodiment the pillar bump may include copper (Cu), aluminum (Al), tin (Sn), nickel (Ni), gold (Au), platinum (Pt), or an alloy thereof. The solder bump may include solder. In an embodiment, the semiconductor package 10 may be mounted on a lower package, an interposer, a package substrate, etc. via the external connection members 160 to form a package-on-package (POP) device.

As mentioned above, in an embodiment the semiconductor package 10 may include the redistribution wiring layer 100, the encapsulation structure ES stacked on the redistribution wiring layer 100, a plurality of conductive bumps 230 disposed on the encapsulation structure ES, a second sealing member 510 covering the encapsulation structure ES on the redistribution wiring layer 100 and partially exposing the plurality of conductive bumps 230, and the insulating layer 600 covering the upper surface 514 of the second sealing member 510. The encapsulation structure ES may include the first sealing member 500, the substrate 100 disposed on the first sealing member 500, the plurality of semiconductor chips 300 arranged within the first sealing member 500, and the conductive wires 400 as a plurality of vertical conductive structures extending on the chip pads 310 of the plurality of semiconductor chips 300 within the first sealing member 500. The chip pads 310 of the plurality of semiconductor chips 300 may be electrically connected to the redistribution wirings 102 of the redistribution wiring layer 100 by the conductive wires 400.

The insulating layer 600 may be provided with the plurality of bonding pads 610 and the marking pattern 620. The conductive bumps 230 may be interposed between the encapsulation structure ES and the insulating layer 600. The conductive bumps 230 may be interposed between the substrate pads 220 of the substrate 200 and the bonding pads 610 of the insulating layer 600.

The encapsulation structure ES may be bonded on the insulating layer 600 in such a way that the conductive bumps 230 are respectively bonded to (e.g., directly bonded to) the bonding pads 610. According to a comparative example, since the individually separated encapsulation structures are attached to the insulating layer by an adhesive film such as DAF, it may be necessary to separately form an alignment key pattern on the insulating layer. In addition, it may be necessary to form an additional metal film for the marking pattern. In contrast, in an embodiment of the present disclosure, since the encapsulation structure ES is attached using the conductive bumps 230, the encapsulation structure may be easily aligned, the package manufacturing process may be simplified, and the strength of the package may be increased.

Hereinafter, a method of manufacturing the semiconductor package in FIG. 1 will be explained.

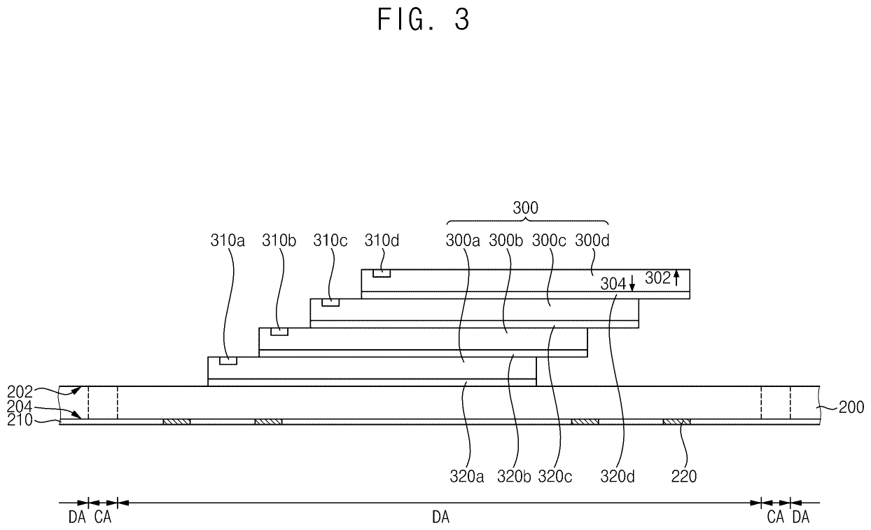

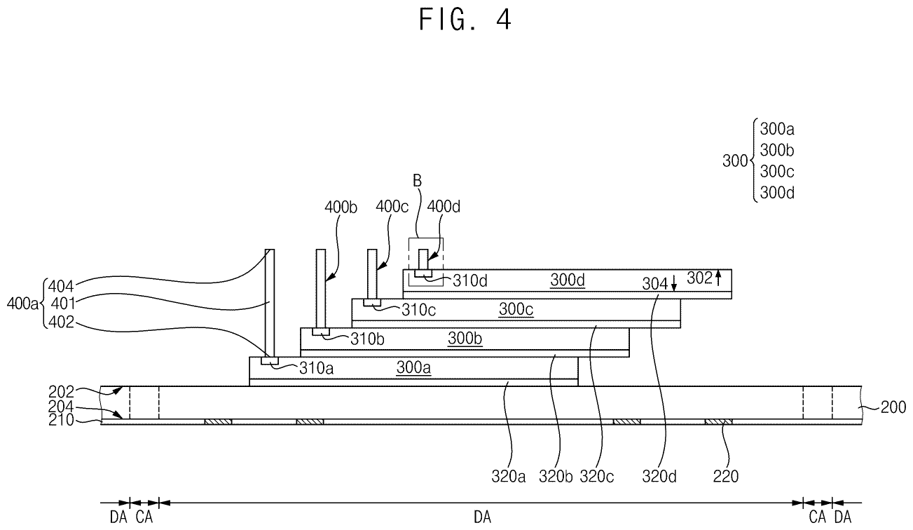

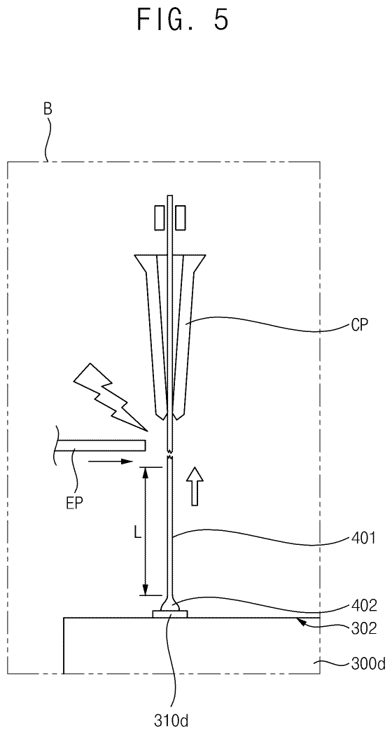

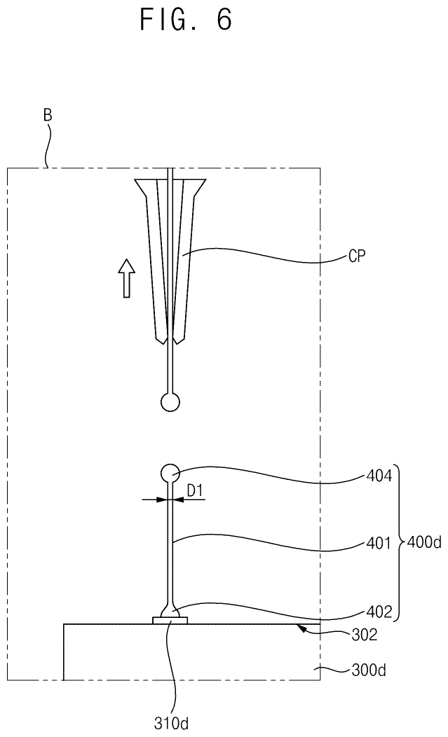

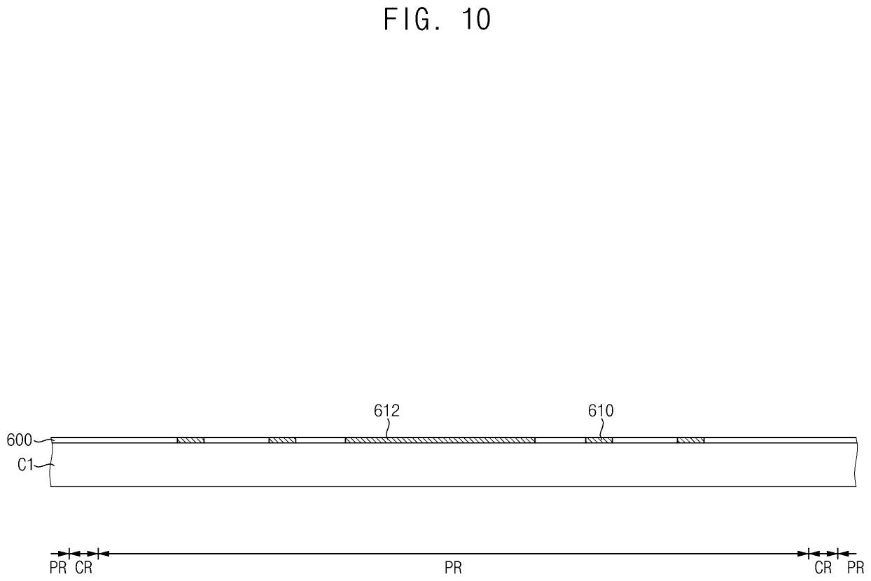

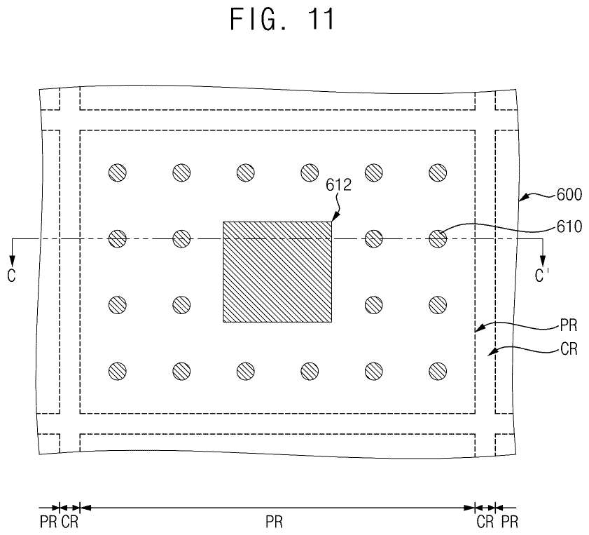

FIGS. 3 to 21 are views illustrating a method of manufacturing a semiconductor package in accordance with example embodiments. FIGS. 3, 4, 7 to 10 and 12 to 21 are cross-sectional views illustrating a method of manufacturing a semiconductor package in accordance with embodiments of the present disclosure. FIGS. 5 and 6 are enlarged cross-sectional views illustrating a process of forming a vertical wire in portion ‘B’ of FIG. 4. FIG. 11 is a plan view of FIG. 10.

Referring to FIG. 3, a plurality of semiconductor chips 300 may be stacked on a substrate 200.

In an embodiment, the substrate 200 may be a multilayer circuit board having a first surface 202 and a second surface 204 opposite to the first surface 202 (e.g., in a vertical direction). The substrate 200 may be a printed circuit board (PCB) having vias and various circuits therein. In an embodiment, the substrate 200 may be a strip substrate for manufacturing a semiconductor strip. Alternatively, the substrate 200 may a glass substrate, a silicon substrate, a ceramic substrate, etc.

The substrate 200 may include a die region DA on which semiconductor chips are arranged and a cutting region CA surrounding the die region DA (e.g., in a plan view). The plurality of semiconductor chips 300 may be arranged on each of the die regions DA of the substrate 200. For example, the substrate 200 may have several tens to several hundreds of die regions DA arranged in a matrix form. As described below, after a first sealing member is formed on the substrate 200 to cover the plurality of semiconductor chips 300, the substrate 200 may be cut along the cutting region CA to form individual encapsulation structures.

In an embodiment, the substrate 200 may include a plurality of substrate pads 220 on the second surface 204 and a passivation layer 210 having openings that expose the plurality of substrate pads 220. As described below, the plurality of substrate pads 220 may be used as bonding pads on which a plurality of conductive bumps are disposed respectively. The plurality of substrate pads 220 may be dummy pads to which no electrical signal is transmitted. For example, in an embodiment the passivation layer may include a photosensitive polymer such as photo solder resist (PSR) or a photosensitive resin such as photo epoxy.

In an embodiment, four semiconductor chips 300a, 300b, 300c and 300d may be sequentially attached onto the first surface 202 of the substrate 200 using adhesive films 320a, 320b, 320c, and 320d. However, embodiments of the present disclosure are not necessarily limited thereto and the number of the plurality of semiconductor chips may vary. In an embodiment, the semiconductor chips 300a, 300b, 300c and 300d may be sequentially attached to the substrate 200 using the adhesive films such as a die attach film (DAF) by a die attach process. For example, in an embodiment a thickness of the semiconductor chip may be within a range of about 40 μm to about 110 μm. A thickness of the adhesive film may be within the range of about 10 μm to about 60 μm.

The semiconductor chips 300a, 300b, 300c, and 300d may be arranged such that a backside surface 304 opposite to a front surface 302 on which chip pads 310a, 310b, 310c, and 310d are formed, such as an inactive surface faces the substrate 200. In an embodiment, each of the semiconductor chips 300a, 300b, 300c, and 300d may have a quadrangular shape having four sides when viewed in plan view. The chip pads 310 may be disposed in a peripheral region along one side of each of the semiconductor chips 300a, 300b, 300c and 300d.

In an embodiment, the semiconductor chips 300a, 300b, 300c and 300d may be stacked in a cascade structure on the substrate 200. The second semiconductor chip 300b may be aligned with an offset in a first horizontal direction on the first semiconductor chip 300a. The second semiconductor chip 300b may be offset aligned in the first horizontal direction such that the chip pads 310a of the first semiconductor chip 300a are exposed from the second semiconductor chip 300b. The third semiconductor chip 300c may be aligned with an offset in the first horizontal direction on the second semiconductor chip 300b. The third semiconductor chip 300c may be offset aligned in the first horizontal direction such that the chip pads 310b of the second semiconductor chip 300b are exposed from the third semiconductor chip 300c. The fourth semiconductor chip 300d may be aligned with an offset in a direction opposite to the first horizontal direction on the third semiconductor chip 300c. The fourth semiconductor chip 300d may be offset aligned in the direction opposite to the first horizontal direction such that the chip pads 310c of the third semiconductor chip 300c are exposed from the fourth semiconductor chip 300d.

In an embodiment, each of the first, second, and third semiconductor chips 300a, 300b, and 300c may have an overhang portion protruding from one side of each of the overlying second, third, and fourth semiconductor chips 300b, 300c, and 300d. In an embodiment, when viewed from a plan view, the chip pads 310a of the first semiconductor chip 300a may be arranged on an upper surface (e.g., the front surface 302) of the overhang portion protruding from one side of the second, third, and fourth semiconductor chips 300b, 300c, and 300d to be spaced apart from each other along a second horizontal direction perpendicular to the first horizontal direction. When viewed from plan view, the chip pads 310b of the second semiconductor chip 300b may be arranged on an upper surface (e.g., the front surface 302) of the overhang portion protruding from one side of the third and fourth semiconductor chips 300c and 300d to be spaced apart from each other along the second horizontal direction. When viewed from plan view, the chip pads 310c of the third semiconductor chip 300c may be arranged on an upper surface (e.g., the front surface 302) of the overhang portion protruding from one side of the fourth semiconductor chip 300d to be spaced apart from each other along the second horizontal direction.

The semiconductor chip may include a memory chip including a memory circuits. For example, in an embodiment the semiconductor chip may include volatile memory devices such as SRAM devices or DRAM devices, and non-volatile memory devices such as flash memory devices, PRAM devices, MRAM devices or RRAM devices.

It will be understood that the number, size, arrangement, etc. of the semiconductor chips are provided as an example, and embodiments of the present inventive concept are not necessarily limited thereto. Also, although only a few chip pads are illustrated in the figures, it will be understood that the structure, shape, and arrangement of the chip pads are provided as an example, and embodiments of the present inventive concept are not necessarily limited thereto.

Referring to FIGS. 4 to 6, conductive wires 400 as a plurality of vertical conductive structures may be formed on the plurality of semiconductor chips 300a, 300b, 300c and 300d. The conductive wires 400a, 400b, 400c, and 400d may be formed on (e.g., formed directly thereon) the chip pads 310a, 310b, 310c, and 310d of the first, second, third, and fourth semiconductor chips 300a, 300b, 300c, and 300d, respectively.

In an embodiment, the conductive wires 400 may be formed by a bonding wire process. The conductive wires 400 may be bonding wires formed by the bonding wire process.

As illustrated in FIGS. 5 and 6, in an embodiment after one end portion of a wire drawn from a capillary CP is bonded to the chip pad 310d of the fourth semiconductor chip 300d, the capillary CP may then move in an upward vertical direction to withdraw the wire. The wire may be pulled out while moving in the vertical direction. When the wire is extended by a predetermined length (L), a portion of the wire may be cut to form the conductive wire 400d. When cutting a portion of the wire, a free air ball FAB may be formed in the cut portion of the wire. For example, an Electronic Flame-Off (EFO) electrode (EP) may be moved adjacent to the cut portion (e.g., the free end) of the wire and a spark may be generated between the EFO electrode (EP) and the cut portion of the wire to from a ball at a new free end.

Thus, the conductive wire 400d may include a wire body 401 extending in the vertical direction, a first bonding end portion 402 provided at a first end portion of the wire body 401 and bonded to the chip pad 310d, and a second bonding end portion 404 provided at a second end portion opposite to the first end portion of the wire body 401 and having a ball shape. The wire body 401 may have a first diameter, and the second bonding end portion 404 may have a second diameter that is greater than the first diameter. For example, in an embodiment the first diameter and the second diameter may be within a range of about 15 μm to about 50 μm.

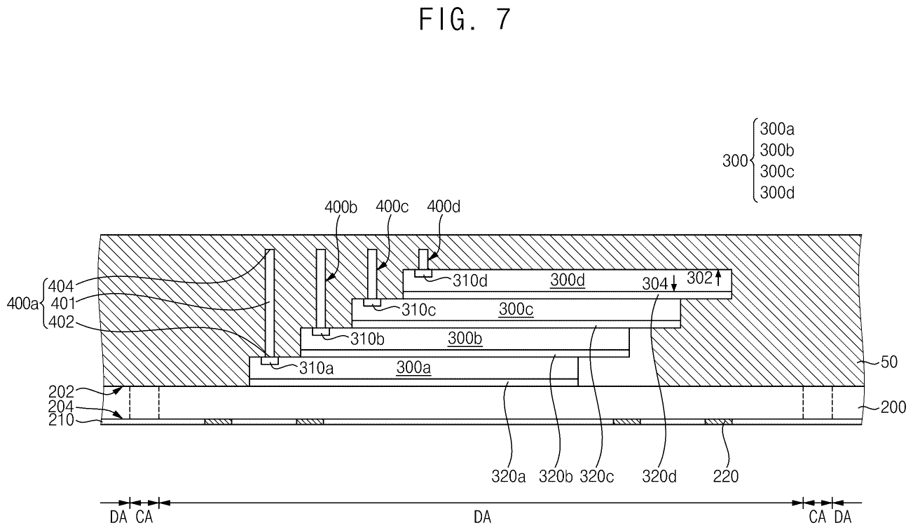

Referring to FIG. 7, a first sealing material 50 may be formed on the first surface 202 of the substrate 200 to cover the plurality of semiconductor chips 300 and the conductive wires 400.

In an embodiment, the first sealing material 50 may be formed on (e.g., formed directly thereon) the upper surface of the substrate 200 to cover the plurality of semiconductor chips 300, and an upper portion of the first sealing material 50 may be removed to have a desired height. The first sealing material 50 may be formed to completely cover the conductive wires 400. In an embodiment, the first sealing material 50 may include a thermosetting resin, for example, epoxy mold compound (EMC).

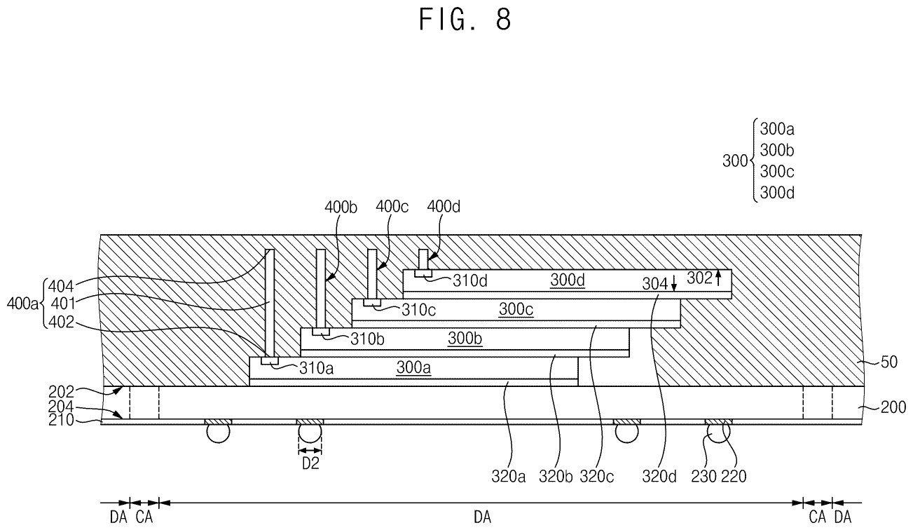

Referring to FIG. 8, a plurality of conductive bumps 230 may be formed on (e.g., formed directly thereon) the plurality of substrate pads 220 of the substrate 200, respectively. The conductive bumps 230 may include solder bumps, micro balls, etc. In an embodiment, a diameter D2 of each of the conductive bumps 230 may be within a range of about 20 μm to about 50 μm.

For example, in an embodiment a seed layer may be formed on the passivation layer 210 of the substrate 200, and a photoresist pattern having openings that expose substrate pad regions may be formed on the seed layer. In an embodiment, after filling the openings of the photoresist pattern with a conductive material, the photoresist pattern may then be removed and a reflow process may be performed to form the conductive bumps 230. For example, in an embodiment the conductive material may be formed on the seed layer by a plating process. Alternatively, the bump may be formed by a screen printing process, a deposition process, a solder ball attach process, etc.

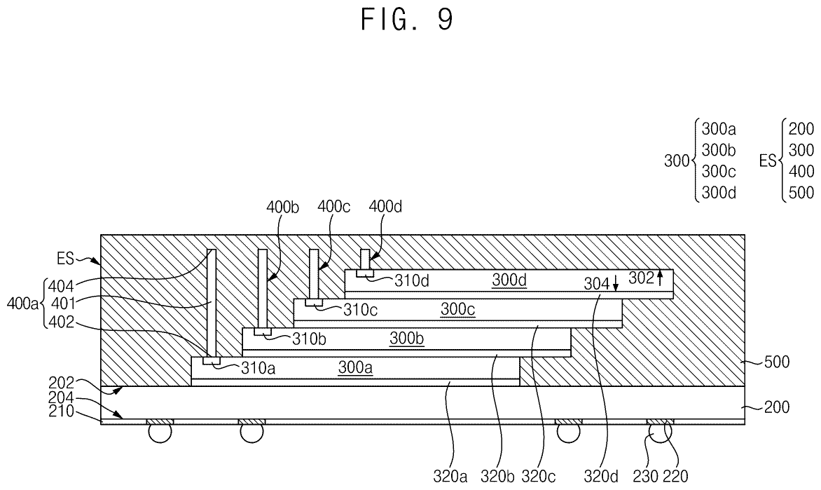

Referring to FIG. 9, the substrate 200 and the first sealing member 50 may be cut along the cutting region CA to form individual encapsulation structures ES. In an embodiment, the substrate 200 and the first sealing material 50 may be cut by a sawing process to form the encapsulation structure ES including the substrate 200 and a first sealing member 500 formed on the substrate 200. An outer side surface of the substrate 200 may be located on the same plane as an outer side surface of the first sealing member 500. For example, as shown in an embodiment of FIG. 9 both outer side surfaces of the substrate 200 may be co-planar with both outer side surfaces of the first sealing member 50 after the first sealing member 50 and the substrate 200 are cut along the cutting region CA.

The encapsulation structure ES may include the substrate 200, the plurality of semiconductor chips 300 sequentially stacked on the substrate 200, the conductive wires 400 extending upward from the chip pads 310 of the plurality of semiconductor chips 300, and the first sealing member 500 covering the plurality of semiconductor chips 300 and the conductive wires 400 on the substrate 200. In addition, the encapsulation structure ES may further include the plurality of conductive bumps 230 disposed on the second surface 204 of the substrate 200.

Referring to FIGS. 10 to 17, the encapsulation structure ES may be placed on a first carrier substrate C1, a redistribution wiring layer 100 may be formed on a surface of the encapsulation structure ES, and a plurality of external connection members 160 may be formed on the redistribution wiring layer 100.

As illustrated in FIG. 10, an insulating layer 600 having a plurality of bonding pads 610 and a marking pattern pad 612 may be formed on (e.g., formed directly thereon) the first carrier substrate C1.

In an embodiment, the first carrier substrate C1 may be provided as a base substrate on which the plurality of encapsulation structures ES are arranged, a second sealing material is formed and a redistribution wiring layer is formed. The first carrier substrate C1 may have a shape corresponding to a wafer on which semiconductor manufacturing processes are performed. For example, in an embodiment the first carrier substrate C1 may include a glass substrate, a silicon substrate, a non-metallic or metallic plate, etc.

The first carrier substrate C1 may include a package region PR in which the encapsulation structure ES including the semiconductor chips is mounted and a cutting region CR surrounding the package region PR (e.g., in a plan view). As described below, the redistribution wiring layer and the second sealing material formed on the first carrier substrate C1 may be cut along the cutting region CR that divides the plurality of package regions PR to be individualized.

In an embodiment, after forming a release film, a barrier metal layer, a seed layer, and the insulating layer 600 on the first carrier substrate C1, the insulating layer 600 may be patterned to form openings that expose bonding pad regions and a pad region for a marking pattern. In an embodiment, a plating process may then be performed on the seed layer to form the bonding pads 610 and the marking pattern pad 612 in the openings.

For example, in an embodiment the insulating layer 600 may include a polymer, a dielectric layer, etc. In an embodiment, the insulating layer 600 may include a photosensitive insulating material (PID). The insulating layer 600 may include a photosensitive polymer such as photo solder resist (PSR) or a photosensitive resin such as photo epoxy. In an embodiment, the insulating layer may be formed by a spin coating process, a vapor deposition process, or the like. The bonding pad and the marking pattern pad may include copper (Cu), aluminum (Al), tin (Sn), nickel (Ni), gold (Au), platinum (Pt), or an alloy thereof.

In an embodiment in which the insulating layer includes a photosensitive insulating material such as PID, the photosensitive insulating layer may be patterned by an exposure process and a development process to form the openings that expose the bonding pad regions and the pad region for the marking pattern. In an embodiment, a curing process of the photosensitive insulating layer may then be performed to form the openings. A plating process may then be performed to form the bonding pads and the marking pattern pad in the openings of the photosensitive insulating layer.

As illustrated in FIG. 11, the marking pattern pads 612 may be positioned in a central region of the package region PR, and the bonding pads 610 may be positioned in a peripheral region surrounding the central region. The bonding pads 610 may be spaced apart from each other in the peripheral region so as to surround the marking pattern pad 612 (e.g., in a plan view).

As described below, the encapsulation structure ES of FIG. 9 may be bonded on the insulating layer 600 such that the conductive bumps 230 are respectively bonded to the bonding pads 610. According to a comparative example, since the individually separated encapsulation structures are attached on the insulating layer by an adhesive film such as DAF, it may be necessary to separately form an alignment key pattern in the insulating layer. In addition, it may be necessary to form an additional metal layer for the marking pattern. However, in an embodiment of the present disclosure, since the encapsulation structure ES is attached using the conductive bumps 230, the encapsulation structure may be easily aligned, the package manufacturing process may be simplified, and the strength of the package may be increased.

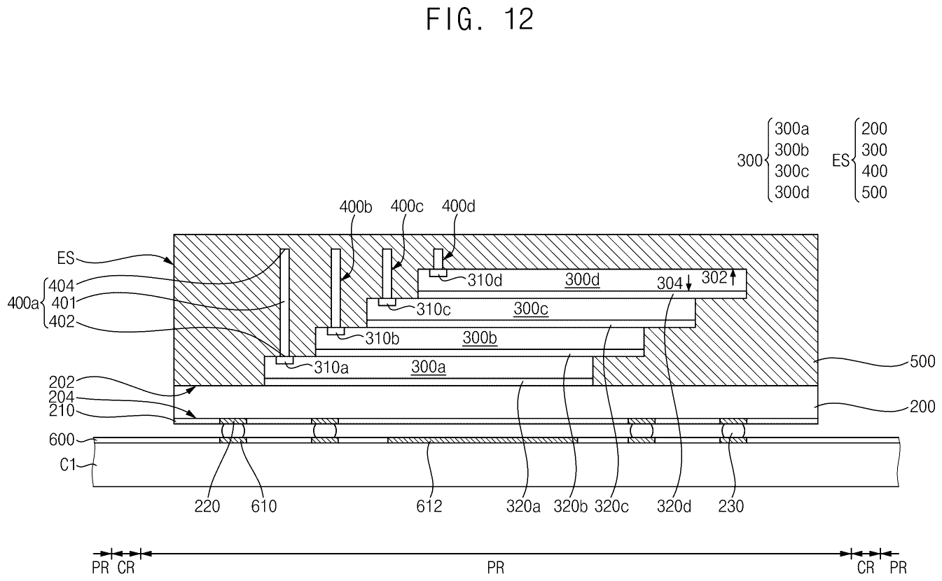

As illustrated in FIG. 12, the encapsulation structure ES of FIG. 9 may be stacked on the insulating layer 600 on the first carrier substrate C1. The encapsulation structure ES may be bonded on the insulating layer 600 via the plurality of conductive bumps 230.

For example, in an embodiment the plurality of conductive bumps 230 of the encapsulation structure ES may be respectively disposed on the plurality of bonding pads 610, and the conductive bumps 230 may be reflowed to be bonded to the bonding pads 610. The conductive bumps 230 may be interposed between the substrate pads 220 of the substrate 200 of the encapsulation structure ES and the bonding pads 610 of the insulating layer 600 (e.g., in a vertical direction).

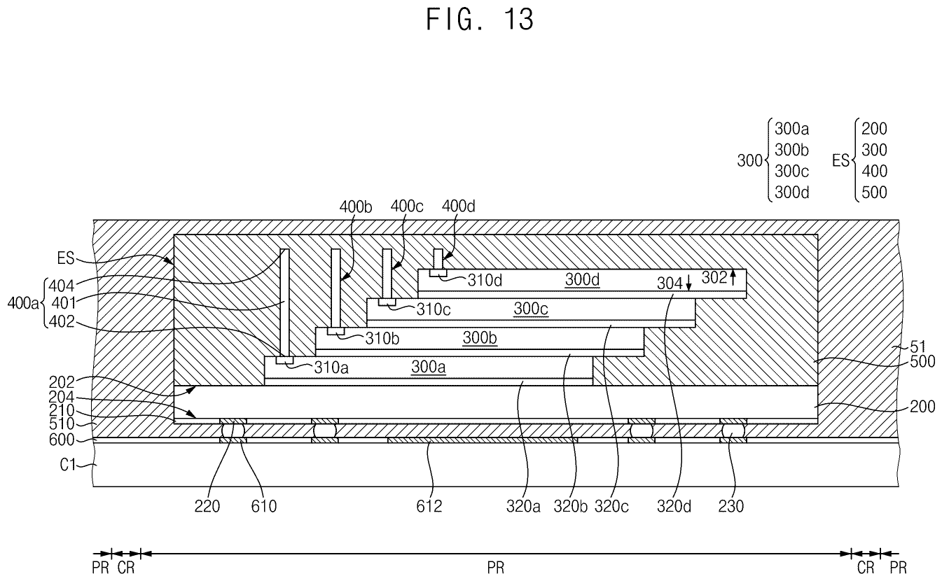

As illustrated in FIG. 13, a second sealing material 51 may be formed on the insulating layer 600 to cover the encapsulation structure ES.

In example embodiments, the second sealing material 51 may be formed on (e.g., formed directly thereon) the insulating layer 600 on the first carrier substrate C1 to cover the encapsulation structure ES, and an upper portion of the second sealing material 51 may be partially removed to have a desired height. The second sealing material 51 may be formed to completely cover the encapsulation structure ES.

In addition, in an embodiment the second sealing material 51 may be formed by a wafer level molded underfill process. The second sealing material 51 may be formed to fill a space between the conductive bumps 300 between a lower surface of the encapsulation structure ES and the insulating layer 600. The second sealing material 51 may cover side surfaces of the conductive bumps 350. In an embodiment, the second sealing material 51 may include a thermosetting resin, for example, an epoxy mold compound (EMC).

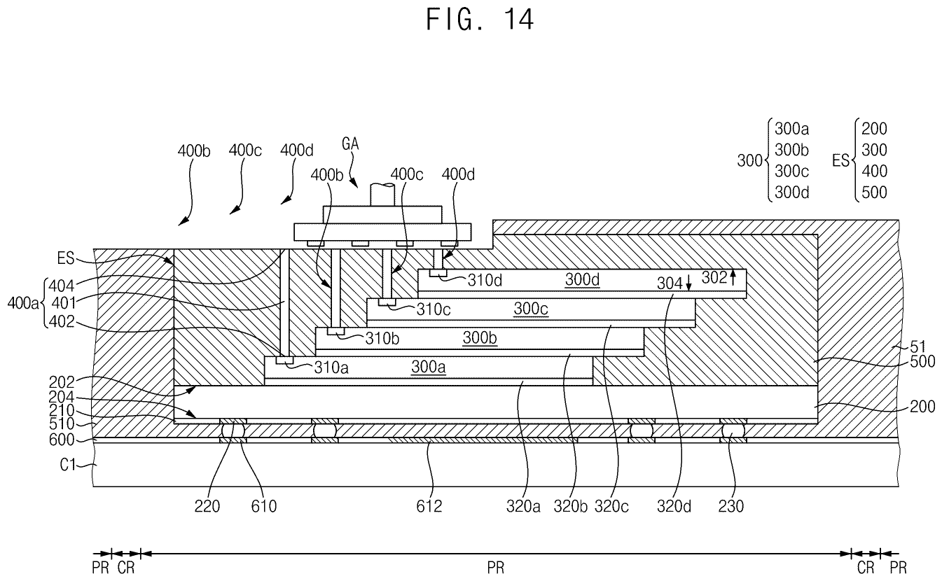

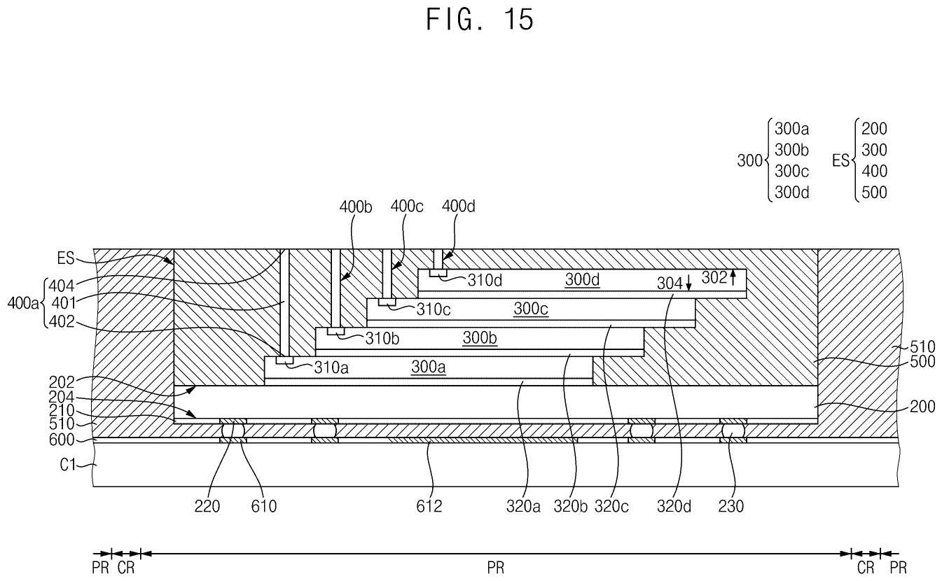

As illustrated in FIGS. 14 and 15, the upper portion of the second sealing material 51 and an upper portion of the first sealing member 500 of the encapsulation structure ES may be partially removed to expose end portions of the conductive wires 400 of the encapsulation structure ES, such as the second bonding end portions 404, respectively. For example, in an embodiment the upper portion of the second sealing material 51 and the upper portion of the first sealing member 500 may be removed by a grinding apparatus GA.

Accordingly, a first surface of the first sealing member 500 may be exposed by a first surface of a second sealing member 510, and the end portions of the conductive wires 400 may be exposed by the first surface of the first sealing member 500.

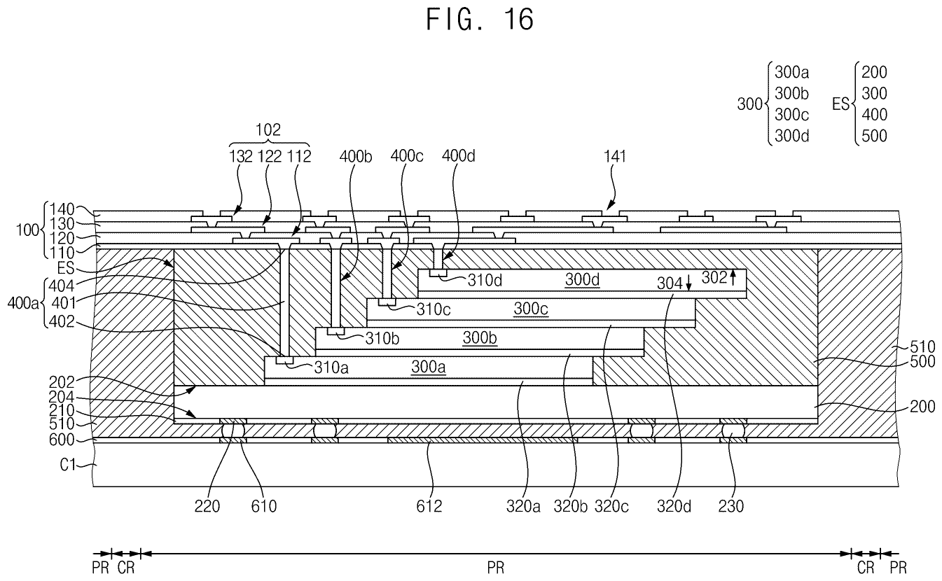

As illustrated in FIG. 16, the redistribution wiring layer 100 having redistribution wirings 102 electrically connected to the conductive wires 400 may be formed on (e.g., disposed directly thereon) the first surface of the first sealing member 500 of the encapsulation structure ES and the first surface of the second sealing member 510.

In an embodiment, after a first lower insulating layer 110 is formed on (e.g., formed directly thereon) the first surface of the first sealing member 500 and the first surface of the second sealing member 510, the first lower insulating layer 110 may be patterned to form first openings. The first openings may expose the end portions of the conductive wires 400, such as the second bonding end portions 404, respectively. In an embodiment, the first lower insulating layer 110 may include a polymer, a dielectric layer, etc. In an embodiment, the first lower insulating layer 110 may be formed by a vapor deposition process, a spin coating process, or the like. In an embodiment, after a seed layer is formed on the exposed end portions of the conductive wires 400 and in the first openings, the seed layer may then be patterned and an electrolytic plating process may be performed to form first redistribution wirings 112. Accordingly, at least portions of the first redistribution wirings 112 may be electrically connected to the conductive wires 400 through the first openings. In an embodiment, the first redistribution wirings may include aluminum (Al), copper (Cu), tin (Sn), nickel (Ni), gold (Au), platinum (Pt), or an alloy thereof.

Similarly, after forming a second lower insulating layer 120 on the first lower insulating layer 110 (e.g., forming directly thereon), the second lower insulating layer 120 may then be patterned to form second openings that expose the first redistribution wirings 112. The second redistribution wirings 122 may then be formed on the second lower insulating layer 120 to be electrically connected to the first redistribution wirings 112 through the second openings.

Similarly, after forming a third lower insulating layer 130 on (e.g., forming directly thereon) the second lower insulating layer 120, the third lower insulating layer 130 may then be patterned to form third openings that expose the second redistribution wirings 122 respectively. The third redistribution wirings 132 may then be formed on the third lower insulating layer 130 to be electrically connected to the second redistribution wirings 122 through the third openings.

In an embodiment, a fourth lower insulating layer 140 may be formed on (e.g., formed directly thereon) the third lower insulating layer 130 to cover the third redistribution wirings 132. The fourth lower insulating layer 140 may serve as a passivation layer. In an embodiment, the fourth lower insulating layer 140 may be partially removed by a via formation process to form openings 141 that expose portions of the third redistribution wirings 132. In an embodiment, a lower bonding pad such as UBM may be formed on the portion of the third redistribution wiring 132 exposed by the fourth lower insulating layer 140 through a plating process.

Thus, the redistribution wiring layer 100 having the redistribution wirings 102 as a front redistribution layer (FRDL) may be formed on the encapsulation structure ES and the second sealing member 510. In an embodiment, the redistribution wiring layer 100 may include the stacked first to fourth lower insulating layers 110, 120, 130, 140 and the redistribution wirings 102 in the first to fourth lower insulating layer 110, 120, 130, 140. The redistribution wirings 102 may include the first, second, and third redistribution wirings 112, 122, 132.

It will be understood that the number, size, arrangement, etc. of the insulating layers and the redistribution wirings of the redistribution wiring layer are provided as an example, and embodiments of the present inventive concept are not necessarily limited thereto.

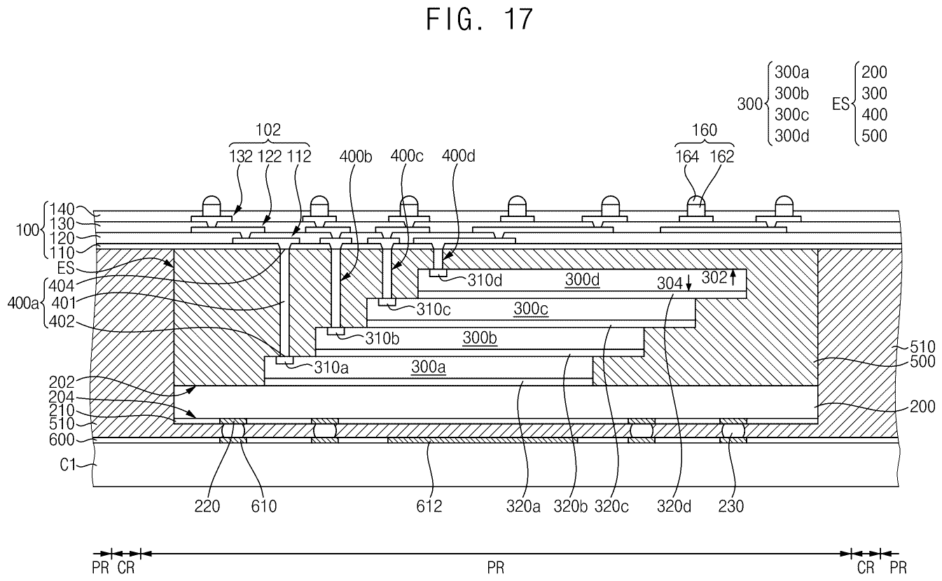

As illustrated in FIG. 17, the external connection members 160 electrically connected to the redistribution wirings 102, respectively, may be formed on the redistribution wiring layer 100.

In an embodiment, a seed layer and a photoresist layer may be formed on the fourth lower insulating layer 140, and an exposure process may be performed to form a photoresist pattern having openings that expose bump regions. In an embodiment, after filling the openings of the photoresist pattern with a conductive material, the photoresist pattern may then be removed, and a reflow process may be performed to form the external connection members 160. Alternatively, the conductive bumps may be formed by a screen printing process, a deposition process, or the like.

For example, a pillar bump 162 may be formed on (e.g., disposed directly thereon) the lower bonding pad on the third redistribution wiring 132 exposed by the fourth lower insulating layer 140, and a solder bump 164 may be formed on (e.g., disposed directly thereon) the pillar bump 162. Accordingly, each of the external connection members 160 may include the pillar bump 162 and the solder bump 164 on the pillar bump 162. For example, in an embodiment the pillar bump may include copper (Cu), aluminum (Al), tin (Sn), nickel (Ni), gold (Au), platinum (Pt), or an alloy thereof. The solder bump may include solder.

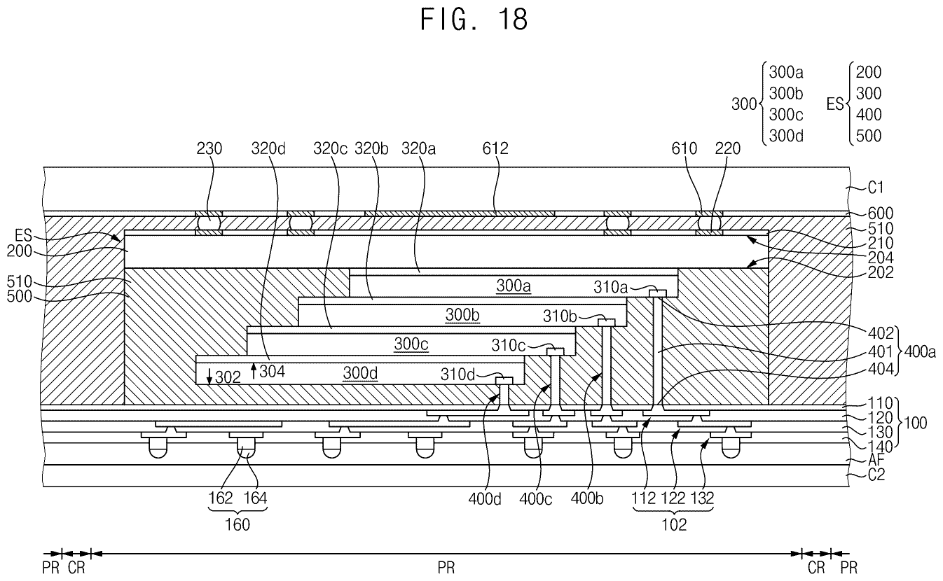

Referring to FIGS. 18 to 20, a marking pattern 620 may be formed in the insulating layer 600.

As illustrated in FIG. 18, an adhesive film AF may be attached on the redistribution wiring layer 100 to cover the external connection members 160, the structure of FIG. 17 may be turned over, and the redistribution wiring layer 100 may be attached on a second carrier substrate C2 using the adhesive film AF.

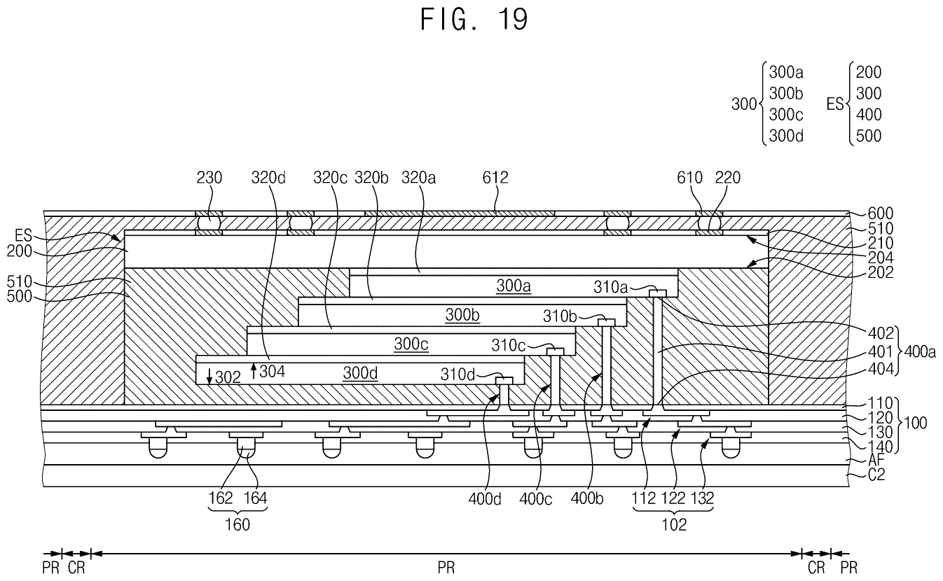

As illustrated in FIG. 19, the first carrier substrate C1 may be removed to expose the insulating layer 600. After removing the first carrier substrate C1, the release film, the barrier metal layer, and a portion of a seed layer pattern may be removed to expose the marking pattern pad 612 of the insulating layer 600.

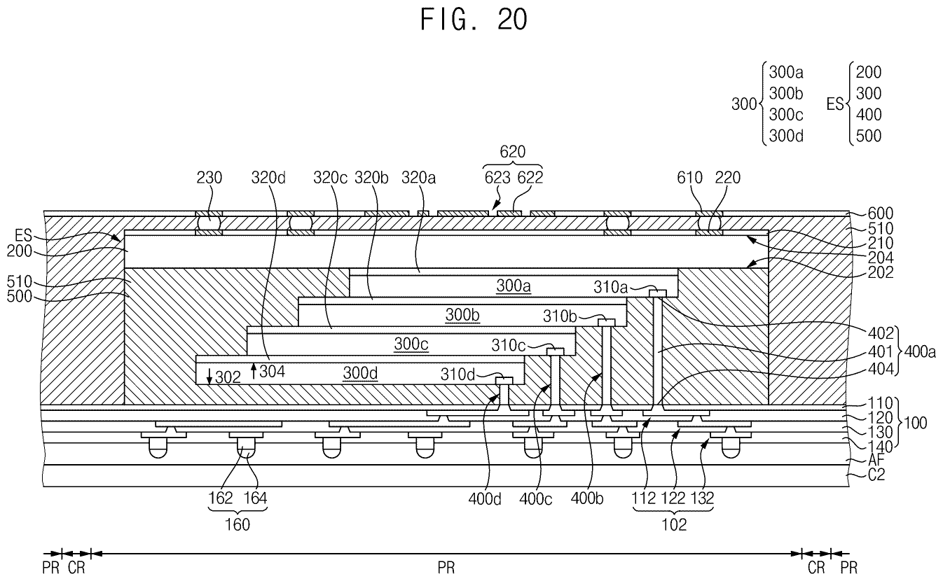

As illustrated in FIG. 20, in an embodiment the marking pattern 620 may be formed by irradiating a laser on the marking pattern pad in the insulating layer 600. Alternatively, the marking pattern 620 may be formed by irradiating a laser on the seed layer on the marking pattern pad 612.

The marking pattern 620 may be formed by a laser processing apparatus. The laser processing apparatus may include an excimer laser apparatus, a diode pumped solid state laser apparatus, etc. In an embodiment, the laser may have a wavelength in a range of about 355 nm to about 532 nm.

The laser processing apparatus may include a scanner optical system and may form an engraved pattern 622 in the marking pattern pad 612. In an embodiment, the engraved pattern 622 may display a manufacturer, a manufacturing date, a serial number, etc. The laser may form openings in a marking dummy pattern 623, and the engraved pattern 622 may be defined by the openings. The openings may include a through hole penetrating the marking dummy pattern 623 or a groove having a predetermined depth.

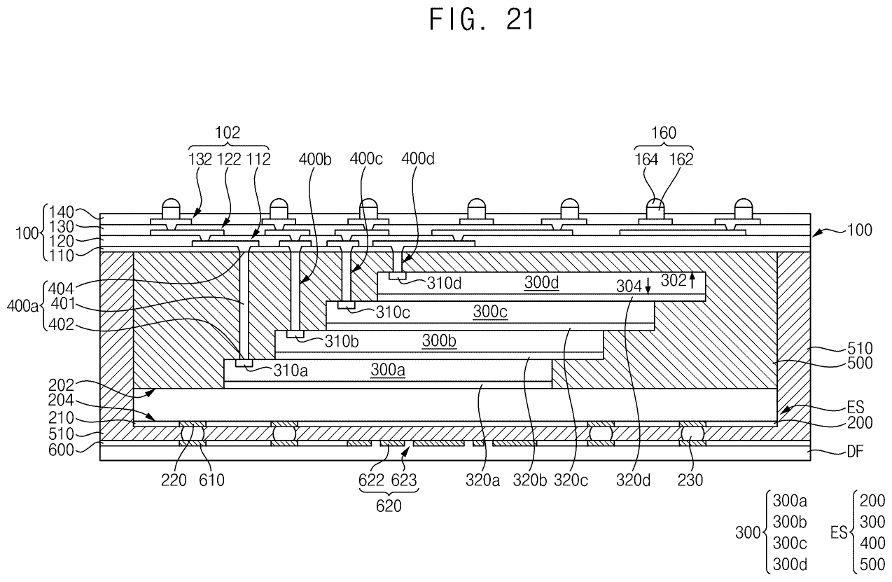

Referring to FIG. 21, the redistribution wiring layer 100 and the second sealing member 510 may be cut along the cutting region to complete a semiconductor package 10 of FIG. 1.

In an embodiment, a dicing tape DF may be attached on (e.g., attached directly thereon) the insulating layer 600, the structure of FIG. 20 may be turned over, and the dicing tape DF may be used to attach the structure to a lower surface of a ring frame. In an embodiment, the second carrier substrate C2 may be removed, the redistribution wiring layer 100 and the second sealing member 510 may be preliminarily cut along the cutting region CR, and the dicing tape DF may be expanded to separate the semiconductor packages 10 individually.

In an embodiment, the redistribution wiring layer 100 and the second sealing member 510 may be cut by a sawing process to form the semiconductor package 10 including the redistribution wiring layer 100, the encapsulation structure ES stacked on the redistribution wiring layer 100, and the second sealing member 510 covering the encapsulation structure ES on the redistribution wiring layer 100. Accordingly, at least one outer side surface of the redistribution wiring layer 100 may be located on the same plane as at least one outer side surface of the second sealing member 510.

The semiconductor package may include semiconductor devices such as logic devices or memory devices. In an embodiment, the semiconductor package may include logic devices such as central processing units (CPUs), main processing units (MPUs), or application processors (APs), or the like, and volatile memory devices such as DRAM devices, HBM devices, or non-volatile memory devices such as flash memory devices, PRAM devices, MRAM devices, ReRAM devices, or the like.

The foregoing is illustrative of example embodiments and is not to be construed as limiting thereof. Although a few example embodiments have been described, those skilled in the art will readily appreciate that many modifications are possible in the described embodiments without materially departing from the novel teachings and advantages of the present inventive concept. Accordingly, all such modifications are intended to be included within the scope of embodiments of the present inventive concept.

1. A semiconductor package, comprising:
a redistribution wiring layer;
an encapsulation structure disposed on the redistribution wiring layer;
a plurality of conductive bumps disposed on the encapsulation structure;
a second sealing member disposed on the redistribution wiring layer and covering the encapsulation structure, the second sealing member partially exposing the plurality of conductive bumps; and
an insulating layer covering an upper surface of the second sealing member and the plurality of conductive bumps,
wherein the encapsulation structure includes:
a first sealing member;
a substrate disposed on an upper surface of the first sealing member;
a plurality of semiconductor chips sequentially disposed within the first sealing member, wherein chip pads of each of the plurality of semiconductor chips are disposed on a front surface of the plurality of semiconductor chips, respectively, the front surface faces the redistribution wiring layer; and
conductive wires extending from a lower surface of the first sealing member to the chip pads of the plurality of semiconductor chips, respectively.

2. The semiconductor package of claim 1, wherein the plurality of conductive bumps is respectively interposed between substrate pads of the substrate and bonding pads of the insulating layer.

3. The semiconductor package of claim 1, wherein the second sealing member fills spaces between the plurality of conductive bumps, an upper surface of the encapsulation structure and the insulating layer.

4. The semiconductor package of claim 1, further comprising:
a plurality of bonding pads disposed in the insulating layer and respectively in direct contact with the plurality of conductive bumps.

5. The semiconductor package of claim 4, further comprising:
a marking pattern arranged in the insulating layer.

6. The semiconductor package of claim 5, wherein the plurality of bonding pads and the marking pattern include a same material as each other.

7. The semiconductor package of claim 1, wherein each of the conductive wires includes:
a wire body extending in a vertical direction;
a first bonding end portion positioned at a first end portion of the wire body and exposed from a lower surface of the first sealing member; and
a second bonding end portion positioned at a second end portion of the wire body opposite to the first end portion and bonded to the chip pads.

8. The semiconductor package of claim 1, wherein the conductive wires include copper (Cu), gold (Au), or aluminum (Al).

9. The semiconductor package of claim 1, wherein the plurality of semiconductor chips include first, second, third, and fourth semiconductor chips stacked in a cascade structure from a lower surface of the substrate,
wherein each of the first, second and third semiconductor chips includes an overhang portion protruding from a first side of underlying second, third and fourth semiconductor chips, and
wherein the chip pads of each of the first, second and third semiconductor chips are disposed on a lower surface of the overhang portion.

10. The semiconductor package of claim 1, wherein at least one outer side surface of the redistribution wiring layer is positioned on a same plane with at least one outer side surface of the second sealing member.

11. A semiconductor package, comprising:
a redistribution wiring layer;
a first sealing member disposed on the redistribution wiring layer;
a plurality of semiconductor chips sequentially disposed in the first sealing member, wherein chip pads of each of the plurality of semiconductor chips are disposed on a front surface of the plurality of semiconductor chips, respectively, the front surface faces the redistribution wiring layer;
conductive wires extending from a lower surface of the first sealing member to the chip pads of the plurality of semiconductor chips, respectively;
a substrate disposed on an upper surface of the first sealing member;
a plurality of conductive bumps disposed on the substrate;
a second sealing member on the redistribution wiring layer and covering the first sealing member and the substrate, the second sealing member partially exposing the plurality of conductive bumps;
an insulating layer covering an upper surface of the second sealing member;
a plurality of bonding pads disposed in the insulating layer and respectively in direct contact with the plurality of conductive bumps; and
a marking pattern arranged in the insulating layer.

12. The semiconductor package of claim 11, wherein the plurality of conductive bumps is respectively interposed between substrate pads of the substrate and bonding pads of the insulating layer.

13. The semiconductor package of claim 11, wherein the second sealing member fills spaces between the plurality of conductive bumps, an upper surface of the substrate and the insulating layer.

14. The semiconductor package of claim 11, wherein each of the conductive wires includes:
a wire body extending in a vertical direction;
a first bonding end portion positioned at a first end portion of the wire body and exposed from the lower surface of the first sealing member; and
a second bonding end portion positioned at a second end portion of the wire body opposite to the first end portion and bonded to the chip pads.

15. The semiconductor package of claim 11, wherein the conductive wires include copper (Cu), gold (Au), or aluminum (Al).

16. The semiconductor package of claim 11, wherein the plurality of semiconductor chips include first, second, third, and fourth semiconductor chips stacked in a cascade structure from a lower surface of the substrate,
wherein each of the first, second and third semiconductor chips includes an overhang portion protruding from a first side of underlying second, third and fourth semiconductor chips, and
wherein the chip pads of each of the first, second and third semiconductor chips are disposed on a lower surface of the overhang portion.

17. The semiconductor package of claim 11, wherein each of the plurality of semiconductor chips include a memory chip.

18. The semiconductor package of claim 11, wherein the plurality of bonding pads and the marking pattern include a same material as each other.

19. The semiconductor package of claim 11, wherein at least one outer side surface of the redistribution wiring layer is positioned on a same plane with at least one outer side surface of the second sealing member.

20. A semiconductor package, comprising:
a redistribution wiring layer;
an encapsulation structure disposed on the redistribution wiring layer, the encapsulation structure including a first sealing member, a plurality of semiconductor chips sequentially stacked in the first sealing member and offset aligned in a first horizontal direction with respect to each other, wherein chip pads of each of the plurality of semiconductor chips are disposed on a front surface of the plurality of semiconductor chips, respectively, the front surface faces the redistribution wiring layer, conductive wires extending from a lower surface of the first sealing member to the chip pads of the plurality of semiconductor chips, and a substrate disposed on an upper surface of the first sealing member;
a plurality of conductive bumps disposed on the substrate;
a second sealing member disposed on the redistribution wiring layer and covering the encapsulation structure, the second sealing member partially exposing the plurality of conductive bumps;
an insulating layer covering an upper surface of the second sealing member;
a plurality of bonding pads disposed in the insulating layer, the plurality of bonding pads is respectively in direct contact with the plurality of conductive bumps; and
a marking pattern arranged in the insulating layer.

21-30. (canceled)
